(19) United States
(12) Patent Application Publication
(10) Pub. No.: US 2004/0121593 A1
(43) Pub. Date: Jun. 24, 2004

(54) Method for manufacturing semiconductor device through use of mask material

(75) Inventor: Takeshi Matsunuma, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Renesas Technology Corp., Tokyo (JP)

(21) Appl. No.: 10/630,747

(22) Filed: Jul. 31, 2003

(30) Foreign Application Priority Data
Nov. 19, 2002 (JP) 2002-335764

(51) Int. Cl. H01L 21/3205; H01L 21/4763; H01L 21/44

(52) U.S. Cl. 438/671; 438/669; 438/585

(57) ABSTRACT

A gate oxide film is formed on a substrate. A polysilicon film is formed on the gate oxide film. A ruthenium film is formed as a mask material on the polysilicon film. A resist pattern is formed on the ruthenium film. After the ruthenium film is patterned using the resist pattern as a mask, a the patterned ruthenium film is shrunk. After the polysilicon film is patterned using a shrunk the shrunken ruthenium film, the shrunk shrunken ruthenium film is removed.

### BACKGROUND OF THE INVENTION

1. Field of the Invention

The present invention relates to a method for manufacturing a semiconductor device, and more specifically to a method for forming a fine pattern through use of a mask material.

2. Description of the Background Art

There has been known a method for forming a fine pattern wherein a silicon oxide film, a silicon nitride film, or a polysilicon film is used as a mask material to etch a film to be processed immediately underneath the mask material.

However, since an etching selectivity of the film to be processed against the mask material is low, shoulders of the mask material are etched when the film to be processed is etched. As shown in FIG. 4, when the amount of the etched shoulders of the mask material is large, an etching of shoulders 33a may also occur in the film to be processed (for example, polysilicon film) 33 disposed immediately underneath the mask material. Here, in FIG. 4, the film to be processed 33 is formed on the gate insulating film 32 formed on the substrate 31.

Since the mask material becomes unnecessary after the film to be processed has been etched, it must be removed. In a conventional method, however, it was difficult to remove only the mask material selectively without etching the film to be processed. Therefore, there was a problem that the thickness of the film to be processed 33 was changed.

Therefore, the conventional method for manufacturing semiconductor devices had a problem of the deterioration of patterns.

### SUMMARY OF THE INVENTION

The present invention has been conceived to solve the previously-mentioned problems and a general object of the present invention is to provide a novel and useful method for manufacturing a semiconductor device.

A more specific object of the present invention is to remove a mask material selectively without etching a film to be processed and is to form a fine pattern easily through use of a mask material.

The above object of the present invention is attained by a following method for manufacturing a semiconductor device.

According to one aspect of the present invention, in the method for manufacturing a semiconductor device, a film to be processed is formed on a substrate. A mask material is formed on the film to be processed. A resist pattern is formed on the mask material. The mask material is patterned using the resist pattern as a mask. The mask material is shrunk. The film to be processed is patterned using a shrunk mask material as a mask. The shrunk mask material is removed.

According to another aspect of the present invention, in the method for manufacturing a semiconductor device, a film to be processed is formed on a substrate. A ruthenium film is formed as a mask material on the film to be processed. A resist pattern is formed on the mask material. The mask material is patterned using the resist pattern as a mask. The film to be processed is patterned using a patterned mask material as a mask. The patterned mask material is removed.

Other objects and further features of the present invention will be apparent from the following detailed description when read in conjunction with the accompanying drawings.

### BRIEF DESCRIPTION OF THE DRAWINGS

FIGS. 1A to 1F are sectional views for illustrating a method for manufacturing a semiconductor device according to a first embodiment of the present invention;

FIGS. 2A to 2E are sectional views for illustrating a method for manufacturing a semiconductor device according to a second embodiment of the present invention;

FIGS. 3A to 3D are sectional views for illustrating a method for manufacturing a semiconductor device according to a third embodiment of the present invention; and

FIG. 4 is a sectional view for illustrating a case that an etching of shoulders occurs in the film to be processed.

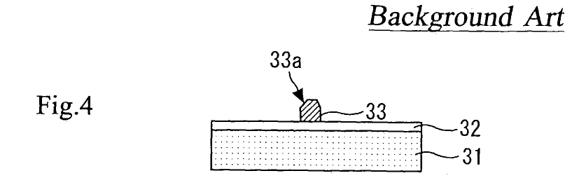

### DETAILED DESCRIPTION OF THE PREFERRED EMBODIMENTS

In the following, principles and embodiments of the present invention will be described with reference to the accompanying drawings. The members and steps that are common to some of the drawings are given the same reference numerals and redundant descriptions therefore may be omitted.

First Embodiment

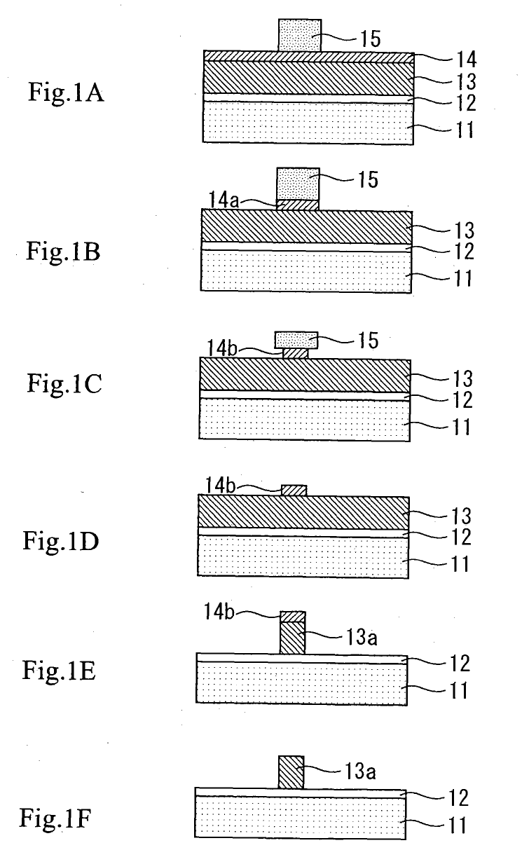

FIGS. 1A to 1F are sectional views for illustrating a method for manufacturing a semiconductor device according to a first embodiment of the present invention. Specifically, FIGS. 1A to 1F are diagrams for illustrating a method for forming a fine gate wiring in an ASIC and the like.

First, as FIG. 1A shows, a gate oxide film of a thickness of about 5 nm is formed as a gate insulating film 12 on a silicon wafer as a substrate 11. A polysilicon film of a thickness of about 150 nm is formed as a gate wiring material 13 on the gate insulating film 12. Next, a ruthenium (Ru) film of a thickness of about 20 nm is formed as a mask material 14 on the gate wiring material 13. Then, a resist pattern 15 is formed on the mask material 14.

Next, as FIG. 1B shows, the mask material 14 is subjected to anisotropic etching using the resist pattern 15 as a mask to form a mask-material pattern 14a. This anisotropic etching is performed, for example, in an ICP (inductively coupled plasma) etching apparatus, and the etching conditions are as follows.

High-frequency power: 1500 W (upper electrode)

200 W (lower electrode)

Pressure: 30 mTorr

Gas: O₂/Cl₂=100/10 sccm

Next, as FIG. 1C shows, the mask-material pattern 14a is subjected to isotropic etching to form a fine mask-material pattern 14b having a pattern width narrower than the pattern width of the mask-material pattern 14a. That is, the mask-material pattern 14a is shrunk or retracted by isotropic etching. This isotropic etching is performed, for example, in an ICP etching apparatus, and the etching conditions are as follows.

High-frequency power: 1500 W (upper electrode)

80 W (lower electrode)

Pressure: 20 mTorr

Gas: O₂/Cl₂=160/20 sccm

Then, as FIG. 1D shows, the resist pattern 15 is removed.

Next, as FIG. 1E shows, the gate wiring material 13 is subjected to anisotropic etching using the fine mask-material pattern 14b as a mask to form a gate wiring 13a. This anisotropic etching is performed, for example, in an ECR etching apparatus, and the etching conditions are as follows.

High-frequency power: 400 W (upper electrode)

30 W (lower electrode)

Pressure: 4 mTorr

Gas: HBr/Cl₂/O₂=70/30/50 sccm

Finally, as FIG. 1F shows, the fine mask-material pattern 14b is removed to form a gate wiring 13a on the gate insulating film 12. The removal of the fine mask-material pattern 14b is performed, for example, in a down-flow-type ashing apparatus, and the ashing conditions are as follows.

Microwave power: 1400 W

Pressure: 2 Torr

Gas: O₂/N₂=900/100 sccm

Temperature: 200° C.

In the first embodiment, as described above, a ruthenium film, which was a metal film, was formed as the mask material 14. After the mask-material pattern 14a was formed by anisotropic etching using the resist pattern 15 as the mask, the mask-material pattern 14a was shrunk by isotropic etching, and the gate wiring 13a was formed by anisotropic etching using the shrunk fine mask-material pattern 14b as the mask.

According to the first embodiment, since the polysilicon film as the gate wiring 13 has a high etching selectivity against the ruthenium film as the mask material 14, the deterioration of the pattern, such as the etching of the mask material can be prevented. Furthermore, the removal of the ruthenium film as the mask material 14 has a high selectivity against the gate wiring material (polysilicon film) and the gate insulating film (oxide film). Therefore, the mask-material pattern 14b can be selectively removed easily without etching the gate wiring material 13a. Hence, change in the film thickness of the gate wiring 13a can be prevented. Therefore, the gate wiring 13a of a desired shape can be formed easily.

Also, since the mask can be shrunk easily, and the fine mask-material pattern 14b can be obtained easily, a fine pattern (fine gate wiring 13a) can be formed easily by using the fine mask-material pattern 14b as the mask.

In the first embodiment, although a ruthenium film is used as the mask material 14, the mask material 14 is not limited to the ruthenium film, but a metal film such as a tungsten (W) film and a titanium nitride (TiN) film can also be used. Here, when a tungsten film is used as the mask material 14, the use of an aqueous solution of H₂O₂ for shrinking and removing the mask material result in the same effect as using the ruthenium film as the mask material. Also, when a titanium nitride film is used as the mask material 14, the use of an aqueous solution of H₂SO₄ for shrinking and removing the mask material result in the same effect.

Also in the first embodiment, although the resist pattern 15 is removed after the mask-material pattern is shrunk, the order may be reversed. That is, after the mask-material pattern has been formed by etching using the resist pattern 15 as the mask, and the resist pattern 15 has been removed, the mask-material pattern may be shrunk. In this case, since the upper surface of the mask-material pattern is also etched when the mask-material pattern is shrunk, the formed thickness of the mask material 14 is increased to, for example, about 60 nm.

Second Embodiment

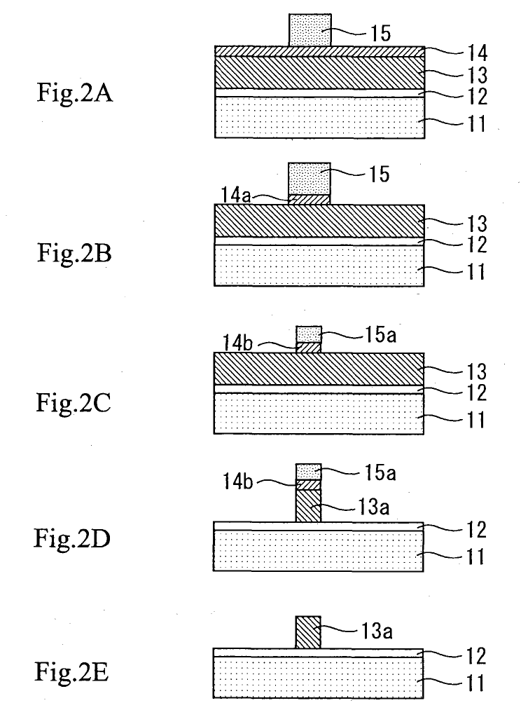

FIGS. 2A to 2E are sectional views for illustrating a method for manufacturing a semiconductor device according to a second embodiment of the present invention. Specifically, FIGS. 2A to 2E are diagrams for illustrating a method for forming a fine gate wiring in an ASIC and the like, as in FIGS. 1A to 1F.

First, as FIG. 2A shows, a gate insulating film 12, a gate wiring material 13, a ruthenium film (Ru film) as a mask material 14, and a resist pattern 15 are formed on a silicon wafer 11 in the same manner as in the above-described first embodiment (refer to FIG. 1A).

Next, as FIG. 2B shows, a mask-material pattern 14a is formed in the same manner as in the first embodiment (refer to FIG. 1B).

Next, as FIG. 2C shows, the resist pattern 15 and the mask-material pattern 14a are subjected to isotropic etching. Thereby, the resist pattern 15 and the mask-material pattern 14a are shrunk or retracted. This isotropic etching is performed, for example, in an ICP etching apparatus, and the etching conditions are as follows.

High-frequency power: 1500 W (upper electrode)

50 W (lower electrode)

Pressure: 50 mTorr

Gas: O₂/Cl₂=200/20 sccm

Next, as FIG. 2D shows, the gate wiring material 13 is subjected to anisotropic etching using the shrunk resist pattern 15a and the shrunk mask-material pattern 14b as a mask to form a gate wiring 13a. This anisotropic etching is performed, for example, in an ECR etching apparatus, and the etching conditions are as follows.

High-frequency power: 400 W (upper electrode)

30 W (lower electrode)

Pressure: 4 mTorr

Gas: HBr/Cl₂/O₂=70/30/50 sccm

Finally, as FIG. 2E shows, the resist pattern 15a and the mask-material pattern 14b is removed to form a gate wiring 13a on the gate insulating film 12. The removal of the resist pattern 15a and the mask-material pattern 14b is performed, for example, in a down-flow-type ashing apparatus, and the ashing conditions are as follows.

Microwave power: 1400 W

Pressure: 2 Torr

Gas: O₂/N₂=900/100 sccm

Temperature: 200° C.

In the second embodiment, as described above, after the mask-material pattern 14a is formed by anisotropic etching using the resist pattern 15 as the mask, the resist pattern 15 and the mask-material pattern 14a are shrunk by isotropic etching, and the gate wiring 13a was formed by anisotropic etching using the shrunk fine resist pattern 15a and the shrunk mask-material pattern 14b as the mask. Thereafter, the resist pattern 15a and the mask-material pattern 14b are simultaneously removed.

According to the second embodiment, after the gate wiring 13a has been formed, the mask-material pattern 14b and the resist pattern 15 can be simultaneously removed under the condition that the Ru film, which is the mask-material pattern 14b, is removed.

Therefore, in addition to the effect obtained in the first embodiment, there is obtained the effect whereby no process step to remove only the resist pattern 15 after transferring the pattern onto the Ru film is required, and the number of manufacturing process steps can be reduced.

Third Embodiment

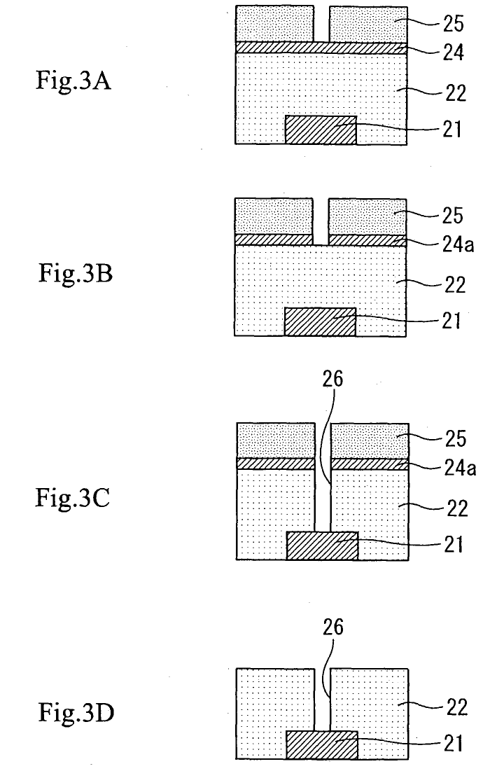

FIGS. 3A to 3D are sectional views for illustrating a method for manufacturing a semiconductor device according to a third embodiment of the present invention. Specifically, FIGS. 3A to 3D are sectional views for illustrating a method for forming a via hole connected to metal wirings in an ASIC or a memory element such as a DRAM.

First, as FIG. 3A shows, an under-layer wiring 21 is formed on a substrate (not shown), and a silicon oxide film (such as a TEOS film, a BSG film, and a BPSG film) of a thickness of about 1.5 μm is formed as an interlayer insulating film 22 above the under-layer wiring 21. Next, a ruthenium (Ru) film of a thickness of about 30 nm is formed as a mask material 24 on the interlayer insulating film 22. Then, a resist pattern 25 is formed on the mask material 24.

Next, as FIG. 3B shows, the mask material 24 is subjected to anisotropic etching using the resist pattern 25 as a mask to form a mask-material pattern 24a. This anisotropic etching is performed, for example, in an ICP etching apparatus, and the etching conditions are as follows.

High-frequency power: 1500 W (upper electrode)

200 W (lower electrode)

Pressure: 30 mTorr

Gas: O₂/Cl₂=100/10 sccm

Next, as FIG. 3C shows, the interlayer insulating film 22 is subjected to anisotropic etching using the resist pattern 25 and the mask-material pattern 24a as a mask to form a via hole 26 reaching the under-layer wiring 21 from the surface of the interlayer insulating film 22. This anisotropic etching is performed, for example, in an ECR etching apparatus, and the etching conditions are as follows.

High-frequency power: 1700 W (upper electrode)

700 W (lower electrode)

Pressure: 4 mTorr

Gas: C₄F₈/Ar/CO=25/200/20 sccm

Finally, as FIG. 3D shows, the resist pattern 25 and the mask-material pattern 24a are removed to form a via hole 26 connected to the under-layer wiring 21 in the interlayer insulating film 22. The removal of the resist pattern 25 and the mask-material pattern 24a is performed, for example, in a down-flow-type ashing apparatus, and the ashing conditions are as follows.

Microwave power: 1400 W

Pressure: 2 Torr

Gas: O₂/N₂=900/100 sccm

Temperature: 200° C.

According to the third embodiment, as described above, after a mask-material pattern 24a had been formed by anisotropic etching using a resist pattern 25 as a mask, a via hole 26 connected to the under-layer wiring 21 was formed in the interlayer insulating film 22 by anisotropic etching using the resist pattern 25 and the mask-material pattern 24a as a mask. Thereafter, the mask-material pattern 24a was removed.

According to the third embodiment, the removal of the ruthenium film as the mask material has a high selectivity against the interlayer insulating film, the metal material (wiring material), and the substrate material. Therefore, the mask-material pattern 24a can be selectively removed easily without etching the interlayer insulating film 22, the under-layer wiring 21, and the substrate. In particular, since the ruthenium film is removed in a dry state using ashing, the dissolution of metal materials as in wet etching does not occur even if the metal materials, such as wirings, are exposed on the surface of the substrate. Therefore, the via hole 26 of a desired shape can be easily formed without etching the interlayer insulating film and the under-layer wiring, that is, without deteriorating the pattern.

Also according to the third embodiment, the mask-material pattern 24a and the resist pattern 25 can be simultaneously removed under the condition that the mask-material pattern 24a is removed after the via hole 26 has been formed. Therefore, there is obtained the effect whereby no process step to remove only the resist pattern 25 after transferring the pattern onto the Ru film is required, and the number of manufacturing process steps can be reduced.

Although a method for forming a via hole connected to the under-layer wiring 21 was described in the third embodiment, the present invention can also be applied to the formation of a contact hole connected to the substrate. In this case, since wet etching can be used for removing the mask material, a metal film other than a ruthenium film, such as a tungsten film and a titanium nitride film can be formed as the mask material. An aqueous solution of H₂O₂ can be used for removing the tungsten film; and an aqueous solution of H₂SO₄ can be used for removing the titanium nitride film.

Although the number of manufacturing process steps increases, only the resist pattern 25 can be removed after a mask-material pattern 24a has been formed as in the first embodiment, and the via hole 26 can be formed using the mask-material pattern 24a as a mask.

This invention, when practiced illustratively in the manner described above, provides the following major effects:

According to the present invention, the mask material can be selectively removed without etching the film to be processed. Also according the present invention, a fine pattern can be easily formed through use of the mask material.

Further, the present invention is not limited to these embodiments, but variations and modifications may be made without departing from the scope of the present invention.

The entire disclosure of Japanese Patent Application No. 2002-335764 filed on Nov. 19, 2002 containing specification, claims, drawings and summary are incorporated herein by reference in its entirety.

What is claimed is:

1. A method for manufacturing a semiconductor device comprising the steps of;
forming a film to be processed on a substrate;
forming a mask material on the film to be processed;
forming a resist pattern on the mask material;
patterning the mask material using the resist pattern as a mask;
shrinking a patterned mask material;
patterning the film to be processed using a shrunk mask material as a mask; and
removing the shrunk mask material.

2. The method for manufacturing a semiconductor device according to claim 1,
wherein a metal film is formed as the mask material.

3. The method for manufacturing a semiconductor device according to claim 2,
wherein a ruthenium film is formed as the mask material, and
the shrunk mask material is removed together with the resist pattern using oxygen-containing plasma.

4. A method for manufacturing a semiconductor device comprising the steps of;
forming a film to be processed on a substrate;
forming a ruthenium film as a mask material on the film to be processed;
forming a resist pattern on the mask material;
patterning the mask material using the resist pattern as a mask;
patterning the film to be processed using a patterned mask material as a mask; and
removing the patterned mask material.

5. The method for manufacturing a semiconductor device according to claim 4,
wherein the patterned mask material is removed together with the resist pattern using oxygen-containing plasma.

6. The method for manufacturing a semiconductor device according to claim 5,
wherein the patterned mask material is removed in the state that a metal material is exposed on the substrate.
